(19) United States
(12) Patent Application Publication
(10) Pub. No.: US 2009/0170234 A1
(43) Pub. Date: Jul. 2, 2009

(54) Image Sensor and Method for Manufacturing Thereof

(76) Inventor: Jin Won Lee, Eumseong-gun (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/261,479

(22) Filed: Oct. 30, 2008

(30) Foreign Application Priority Data
Dec. 27, 2007 (KR) 10-2007-0139272

(51) Int. Cl. H01L 31/18

(52) U.S. Cl. 438/98; 257/E31.085

(57) ABSTRACT

Disclosed is a method for manufacturing an image sensor. The method includes a process for removing foreign matter from a non-device area of a wafer before forming contacts in a device area of the wafer. According to an embodiment, an insulating layer formed in the non-device area is removed by performing a first process with respect to the non-device area. Then, a contact can be formed in the insulating layer in the device area.

### CROSS-REFERENCE TO RELATED APPLICATION

The present application claims the benefit under 35 U.S.C. §119 of Korean Patent Application No. 10-2007-0139272, filed Dec. 27, 2007, which is hereby incorporated by reference in its entirety.

### BACKGROUND

In general, an image sensor is a semiconductor device for converting optical images into electric signals, and is generally classified as a charge coupled device (CCD) or a CMOS image sensor (CIS).

The CMOS image sensor is a device employing a switching mode to sequentially detect an electric signal of each unit pixel by providing photodiodes and MOS transistors in unit pixels.

### BRIEF SUMMARY

Embodiments of the present invention can provide a method for reducing damage of a device area of an image sensor due to foreign matters from a non-device area of the wafer.

According to an embodiment, a method for manufacturing an image sensor can include preparing a wafer comprising a device area having a photodiode and a gate, a non-device area, and an insulating layer on the device area and the non-device area; removing insulating layer formed on the non-device area by performing a first process with respect to the non-device area; and forming a contact in the insulating layer in the device area.

According to embodiments, an image sensor can be provided that includes a wafer substrate having a first region formed with devices including a photodiode and a gate, and a second region at an edge area of the wafer substrate and formed with no devices; and an insulating layer on the first and second areas, wherein the wafer substrate is exposed through a part of the second region.

### BRIEF DESCRIPTION OF THE DRAWINGS

FIG. 1 is a plan view showing a wafer including a device area and a non-device area.

FIG. 2, and FIGS. 4 and 5 are cross-sectional views showing a device area and a non-device area of a wafer according to an embodiment.

FIG. 3 is a view showing the mounting of a wafer in a process chamber in accordance with an embodiment of the present invention.

### DETAILED DESCRIPTION

Hereinafter, embodiments of an image sensor and method for manufacturing thereof will be described with respect to accompanying drawings.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

In the following description, although the structure of a CMOS image sensor (CIS) is described with respect to accompanying drawings, embodiments are not limited thereto. For example disclosed process steps are adaptable for all image sensors fabricated on wafers, including a charge coupled device (CCD) image sensor.

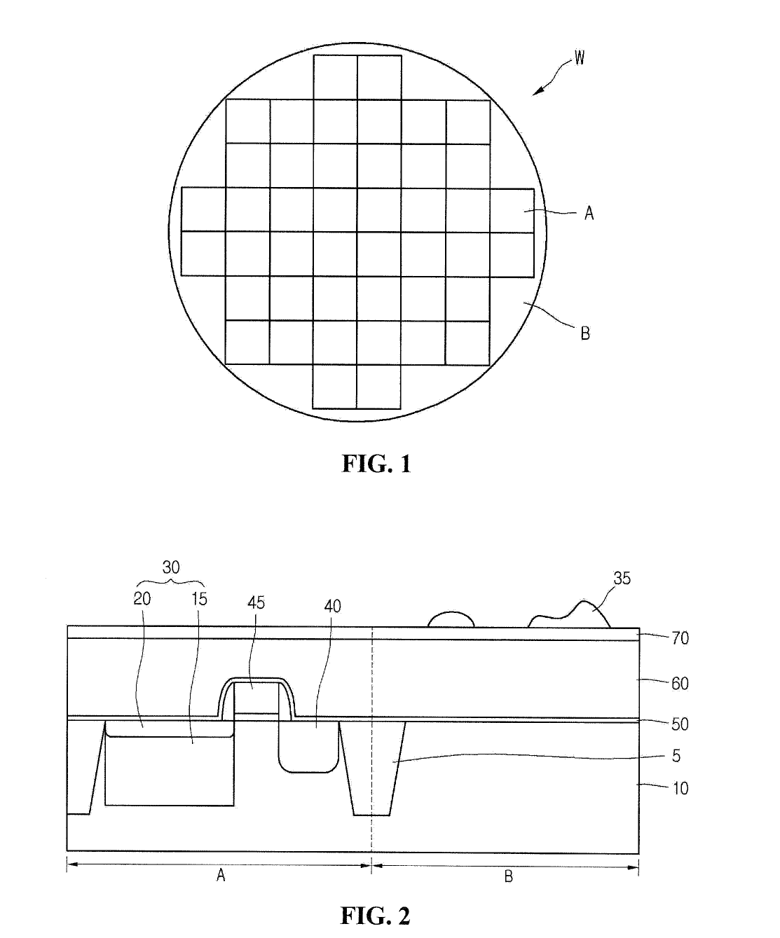

A method for manufacturing an image sensor according to an embodiment will be described with respect to FIGS. 1-5.

Referring to FIG. 1, a wafer W includes a device area A and a non-device area B.

Each device area A of the wafer can include structures such as a photodiode, a gate, and an insulating layer, and the non-device area B may exclusively include an insulating layer.

Although it is not shown, the insulating layer of the non-device area B often includes other foreign matters.

In particular, a great amount of foreign matters may exist in the non-device area B due to the fabricating processes.

The foreign matters can cause defects of the device area A in a process for forming a device. In particular, defects may occur during contact formation processes due to foreign matters in and on the insulating layer of the non-device area B.

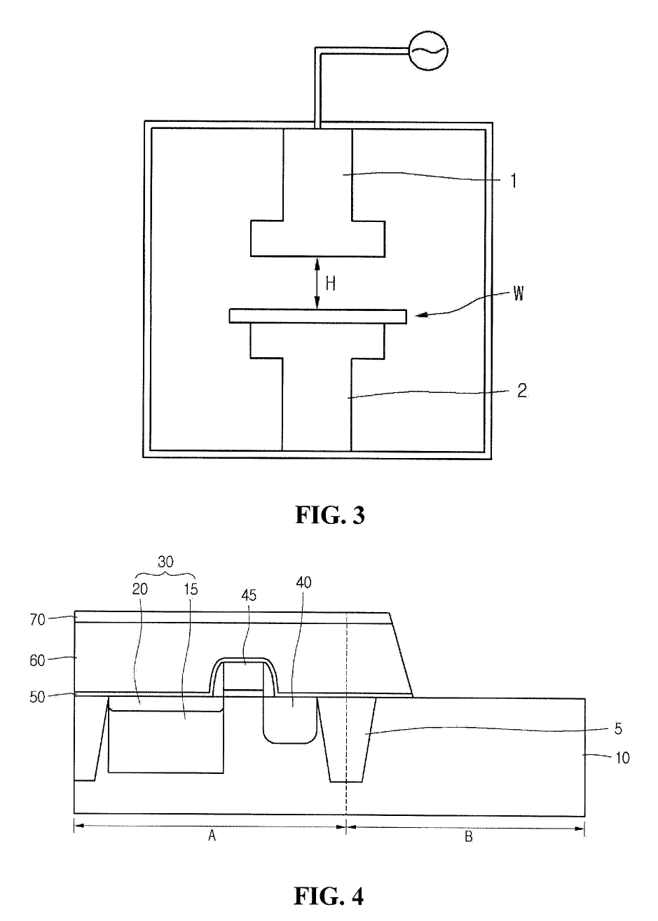

FIG. 2 is a cross-sectional view showing the device area A and the non-device area B of the wafer W, and indicates foreign matter 35.

As shown in FIG. 2, according to one embodiment, in the device area A, a gate 45 is formed on a semiconductor substrate 10 including a photodiode 30 and a floating diffusion area 40. Then, an insulating layer 60 and a protective layer 70 are formed on the semiconductor substrate 10. The insulating layer 60 and the protective layer 70 are also formed on the non-device area B.

In certain embodiments the semiconductor substrate 10 can include a lightly-doped p type epitaxial layer (not shown) on a heavily-doped p++ type silicon substrate.

By providing a lightly-doped p type epitaxial layer, the depletion region of a photodiode can be more widened and deepened. Accordingly, the ability of the photodiode to collect optical charges can be increased.

In addition, when the heavily-doped p++ type substrate is formed under the p type epitaxial layer, optical charges are recombined with each other before the optical charges are diffused into adjacent unit pixels. Accordingly, the random diffusion of the optical charges is reduced, so that variation in delivery function for the optical charges may be reduced.

An isolation layer 5 can be formed in the semiconductor substrate 10. In one embodiment the isolation layer 5 can be formed by forming a trench in the semiconductor substrate 10 and filling an insulating material in the trench.

The gate 45 can be formed, for example, by forming an oxide layer and a polysilicon layer on the semiconductor substrate 10 and then patterning the resultant structure.

For a CIS of the 4-T type, the gate 45 can be a transfer gate.

In further embodiments, the gate 45 can include a metal silicide layer.

The photodiode 30 can include a first impurity area 15 and a second impurity area 20. The first impurity area 15 can be formed by implanting n-type impurities into the substrate 10, and the second impurity area 20 can be formed by implanting p-type impurities into the substrate on the first impurity area 15.

The floating diffusion area 40 can be formed by implanting n-type impurities into the transistor area of the substrate.

In an embodiment a nitride layer 50 can be formed on the semiconductor substrate 10 including the gate 45. T he nitride layer 50 can be used to protect the gate 45, the floating diffusion area 40, and the photodiode 30.

The insulating layer 60 can be used as an interlayer dielectric. In an embodiment, the insulating layer 60 includes an oxide layer.

The protective layer 70 can be formed on the insulating layer to inhibit impurities from penetrating into the insulating layer 60 provided under the protective layer 70, so that defects are inhibited from occurring in a device. In an embodiment, the protective layer can include an oxide layer formed using silane gas (SiH₄).

Foreign matters 35 are often formed on the insulating layer 60 and the protective layer 70 in the non-device area B.

In addition, although it is not shown, the foreign matters are formed even inside the insulating layer 60 of the non-device area B.

In particular, many foreign matters 35 are extensively formed in the non-device area B.

This is because residues can remain in the non-device area B when forming the photodiode 30 and the gate 45 in the device area A.

The above foreign matters 35 cause a stress between lower layers in a subsequent process, so that a defect of a device may occur. Accordingly, a product yield may be reduced, and a process failure may be caused unless defects can be reduced.

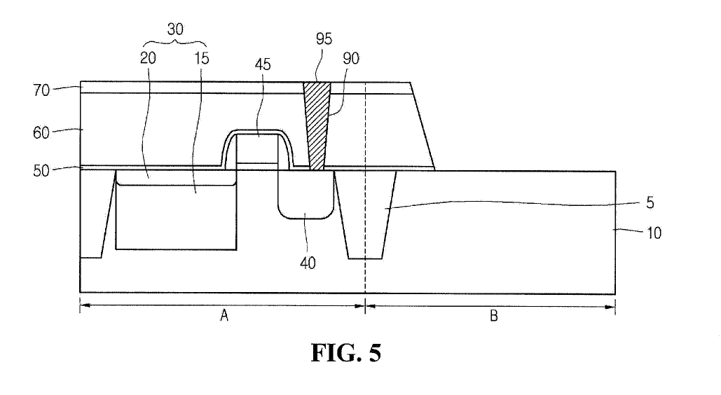

Accordingly, referring to FIG. 3, the wafer W, which includes the device area A including the photodiode 30 and the gate 45 and the non-device area B including the insulating layer 60 and the protective layer 70, is mounted in a process chamber. According to embodiments of the present invention, a first and second process can be carried out in the process chamber to remove foreign matters on the non-device area B.

The wafer W can be provided on a cathode 2 in the process chamber, and an electrode 1 is provided above the wafer W.

The electrode 1 can have a diameter smaller than that of the wafer W by about 1 mm to about 3 mm.

In other words, the wafer W may have a diameter greater than that of the electrode 1 by 30 about 1 mm to about 3 mm.

In addition, the electrode 1 is distanced from the wafer W by a height H of about 0.3 mm to about 0.5 mm.

The distance between the wafer W and the electrode 1 is used to inhibit the device area A of the wafer W from being etched in the following etching process.

If the distance between the wafer W and the electrode 1 is smaller than or greater than the above condition, the device area A may be also etched or the non-device area B may not be etched.

In particular, during the plasma etching process, plasma does not form in the area between electrode 1 and the wafer W on the cathode 2. Instead, the plasma forms spaced apart from the electrode 1 by a predetermined distance.

The distance between the wafer W and the electrode 1 is a region where plasma is not formed. Since the electrode 1 has a diameter smaller than that of the wafer W, the electrode 1 is distanced from the edge of the wafer W by a predetermined distance. Accordingly, plasma may be formed in the non-device area B so that the non-device area B can be etched.

Once the wafer W and electrode 1 are properly aligned, a first and second process according to embodiments of the present invention can be performed with respect to the wafer W.

For example, after arranging the electrode 1 distanced from the wafer W by a height H of 0.3 mm to 0.5 mm, the first process can be performed for 11 seconds to 20 seconds under the pressure of 840 mTorr to 1560 mTorr by providing sulfur hexafluoride (SF₆) gas at a flow rate of 63 sccm to 117 sccm, carbon fluoride (CF₄) gas at a flow rate of 63 sccm to 117 sccm, and oxygen (O₂) gas at a flow rate of 14 sccm to 26 seem.

Then, the second process can be performed under the pressure of 840 mTorr to 1560 mTorr for 14 seconds to 52 seconds by applying RF power of 490 W to 910 W and providing sulfur hexafluoride (SF₆) gas at a flow rate of 63 sccm to 117 sccm, carbon fluoride (CF₄) gas at a flow rate of 63 sccm to 117 sccm, and oxygen (O₂) gas at a flow rate of 14 sccm to 26 seem.

As shown in FIG. 4, the foreign matter 35, the protective layer 70, the insulating layer 60, and the nitride layer 50 can be removed from the non-device area B through the first and second processes performed in the process chamber.

In this case, the substrate 10 of the non-device area B can be exposed through the first and second processes.

In certain embodiments, a portion of the protective layer 70, the insulating layer 60, and the nitride layer 50 on the non-device area B making contact with the device area may remain.

According to an embodiment, the foreign matter 35, the protective layer 70, the insulating layer 60, and the nitride layer 50 can be removed from the non-device area B formed with the foreign matter 35, so that it is possible to reduce stress derived from the foreign matter 35 in subsequent processes. Accordingly, a product yield can be increased, and a device failure may be minimized.

Referring to FIG. 5, a contact 95 can be formed on the floating diffusion area 40 of the device area A.

The contact 95 can be formed by forming a contact hole 90 in the protective layer 70, the insulating layer 60, and the nitride layer 50 and filling a metal material in the contact hole 90.

According to an embodiment, the first and second processes can be performed with respect to the non-device area B before the contact 95 is formed. In addition, when a process of forming the contact 95 is repeated, the first and second processes can be repeatedly performed prior to forming the contact 95.

In other words, the foreign matter 35 can be repeatedly removed from the non-device area B prior to forming the contacts 95 for each contact formation process step, so that a device failure may be minimized. Accordingly, a product yield may be increased.

As described above, in the method for manufacturing an image sensor according to an embodiment, foreign matters causing the defect of a device formed in the non-device area B are removed, so that the stress derived from the foreign matters is reduced in a subsequent process. Accordingly, a product yield can be increased, and the failure of the device can be minimized.

When a device is manufactured, the foreign matters existing on the non-device area can be repeatedly removed prior to forming a contact, so that the failure of the device can be minimized, and a product yield can be increased. Accordingly, the reliability of the image sensor can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing an image sensor comprising:
preparing a wafer having a device area and a non-device area, wherein the device area comprises a photodiode and a transistor arranged according to unit pixel, wherein the non-device area is provided at an outer edge region of the wafer, and wherein an insulating layer is provided on the device area and the non-device area;
removing the insulating layer from at least a portion of the non-device area; and
forming a contact in the insulating layer in the device area after removing the insulating layer from the at least a portion of the non-device area.

2. The method according to claim 1, wherein removing the insulating layer from the at least a portion of the non-device area comprises:
disposing the wafer in a process chamber; and
performing an etching process with respect to the non-device area only.

3. The method according to claim 2, wherein disposing the wafer in the process chamber comprises:
arranging the wafer on a cathode; and
disposing an electrode above the wafer to provide a protective gap.

4. The method according to claim 3, wherein disposing the electrode above the wafer to provide the protective gap comprises:
distancing the electrode a height of between about 0.3 mm and about 0.5 mm from the wafer.

5. The method of claim 3, wherein the electrode has a diameter smaller than that of the wafer.

6. The method of claim 5, wherein a difference between the diameter of the electrode and a diameter of the wafer is in a range of between about 1 mm to about 3 mm.

7. The method according to claim 2, wherein performing the etching process comprises performing a plasma etching process.

8. The method according to claim 7, wherein the plasma etching process is performed under a pressure of 840 mTorr to 1560 mTorr for a predetermined period of time by applying RF power of 490 W to 910 W and providing sulfur hexafluoride (SF₆) at a flow rate 63 sccm to 117 seem, carbon fluoride (CF₄) gas at a flow rate of 63 sccm to 117 sccm, and oxygen (O₂) gas at a flow rate of 63 sccm to 117 sccm.

9. The method according to claim 2, further comprising performing a pre-etch process to remove a portion of the insulating layer before performing the etching process.

10. The method according to claim 9, wherein performing the pre-etch process comprises using plasma.

11. The method according to claim 10, wherein the pre-etch process is performed under a pressure of 840 mTorr to 1560 mTorr for a predetermined period of time by providing sulfur hexafluoride (SF₆) at a flow rate of 63 sccm to 117 sccm, carbon fluoride (CF₄) gas at a flow rate of 63 sccm to 117 sccm, and oxygen (O₂) gas at a flow rate of 14 sccm to 117 sccm.

12. The method according to claim 1, wherein removing the insulating layer from the at least a portion of the non-device area exposes a substrate surface of the non-device area.

13. The method according to claim 1, wherein foreign matters generated when the photodiode and the transistor are formed on the device area exist on the non-device area, and the foreign matters are removed from the non-device area by the removing of the insulating layer from the at least a portion of the non-device area.
